(19) United States
(12) Patent Application Publication
(10) Pub. No.: US 2026/0298841 A1
(43) Pub. Date: Oct. 1, 2026

(54) OPTICAL SEMICONDUCTOR DEFECT DETECTION

(71) Applicant: Intel Corporation, Santa Clara, CA (US)

(72) Inventors: Mark ABEL, Portland, OR (US); Can GUVEN, Portland, OR (US); Todd HOPPE, Portland, OR (US); Charles H. WALLACE, Portland, OR (US)

(21) Appl. No.: 19/094,806

(22) Filed: Mar. 28, 2025

(51) Int. Cl. G01N 21/95; G06T 7/00; H01L 21/67

(52) U.S. Cl. CPC G01N 21/9501; G06T 7/001; H10P 72/0616; G06T 2207/30148

(57) ABSTRACT

Some examples use cell-to-cell based comparison for implementing optical defect identification (e.g., with QTM systems) for flushing out defects in processes used to make one or more semiconductor features.

### BACKGROUND

Quick turn monitoring (QTM) is used in semiconductor defect testing to accelerate the feedback loop between defect detection (identification) and process correction, enabling rapid identification and resolution of manufacturing issues. This approach can combine high-speed optical inspection technologies with real-time data analysis to minimize production delays while maintaining quality standards. However, with ever-decreasing advanced process feature dimensions, it is becoming more and more difficult to effectively use optical defect scanning methods such as QTM. Accordingly, new techniques would be desired.

### BRIEF DESCRIPTION OF THE DRAWINGS

The disclosure may best be understood by referring to the following description and accompanying drawings that are used to illustrate embodiments of the invention. In the drawings:

FIG. 1 is a diagram showing an exemplary conventional QTM test wafer with enlarged views of semiconductor process features that are to be analyzed.

FIGS. 2A and 2B show exemplary defect reference images from die-to-die and cell-to-cell comparisons.

FIG. 3 is a graph showing defect pareto results for exemplary die-to-die and cell-to-cell optical defect detection cases.

FIG. 4A is a diagram showing a defect test reticle layout using cells and cell transition regions between the cells in accordance with some embodiments.

FIG. 4B shows a SEM (scanning electron microscope) image near a cell transition region without fan-out feature distribution near the transition region.

FIG. 4C shows a SEM image near a cell transition region with fan-out feature distribution near the transition region.

FIG. 5 is a block diagram showing an exemplary optical defect identification system in accordance with some embodiments.

FIG. 6 is a flow diagram showing a routine for detecting defects in a semiconductor feature process in accordance with some embodiments.

### DETAILED DESCRIPTION

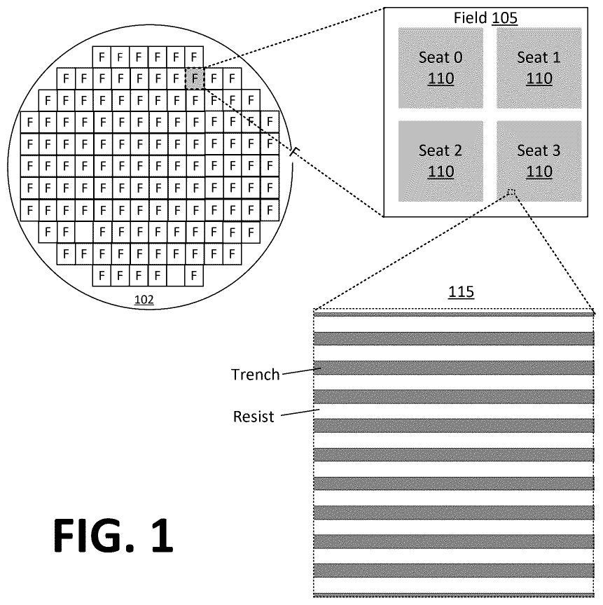

FIG. 1 is a diagram showing an exemplary conventional QTM test wafer with semiconductor process features (e.g., lines, pads, etc.) to be analyzed for defects. The wafer includes a plurality of arrayed fields (F) that include test patterns scanned onto the wafer using a photolithographic reticle scan process. For example, a step and scan process may be used with a reticle to scan the fields, one field at a time, onto the wafer.

The fields may be the same or different, e.g., if different reticles are applied. In addition, the fields could be of any suitable sizes. A typical dimension for a field within this wafer context is around 20 by 30 mm.

The figure shows an enlarged, representative view of one of the fields (F), which is labeled as field 105. It illustrates how each field may be sub-divided into seats 110. With this example, there are four equally sized seats, although there could be more or less seats, and they could be the same or there could be some differently configured seats in a field.

Each seat includes multiple instances of semiconductor process features to be tested or analyzed. Actually, in some implementations, it may be more accurate to say that the processes for making the features, rather than the specific features themselves, are being tested. An extremely large number of feature instances are typically fabricated onto the wafer, and the optical analysis system essentially looks for defects so that the defect causes can be redressed. Millions, if not billions or trillions of repeated feature instances may be needed to generate only a very small number of the feature defects, but they should be identified since even a very small number could severely impair a commercialized implementation of a semiconductor fabrication process using the particular process for the feature in question.

Exemplary features are depicted in the figure, which shows a very small portion 115 of seat 3 significantly enlarged. For example, enlarged portion 115 could be in the neighborhood of 200 nm by 150 nm. The enlarged test wafer portion shows a photo resist layer (white lines) that includes a plurality of spaced apart, parallel-aligned trenches. For this example, the process for making the trench and resist lines is analyzed to look for the many different types of defects that can arise with such nano-scale features. While repeated trench/resist lines are shown in this example, it should be appreciated that other features, or feature geometries, could also be tested. Similarly, the seats may each be different (size, constituent features), or they may be repeated instantiations themselves of the same seat configurations with or without the same feature types in each seat.

As mentioned above, optical systems are used to rapidly scan test wafers such as the wafer 102 of FIG. 1 during production, generating reference defect maps, for example, without having to interrupt the manufacturing flow. To do this, the optical system tools typically compare like areas on the wafer with other like areas. Previously, the inspection tools have been limited to comparison between adjacent fields, or if seats repeat in a field then comparison of adjacent seats. However, it has been observed, and appreciated, that the relatively large distances between fields, or even seats, being compared, can cause a not insubstantial amount of optical noise, which makes it difficult to accurately detect real defects distinguished from those that are false-positives.

Accordingly, new approaches are provided herein. In some embodiments, smaller, cell-based layouts may be used to enhance signal to noise ratios (SNR) for optical images that are obtained for defect analysis.

As described above, typical QTM masks (or reticles) for making field patterns had been composed of seats that contained uniform line/space patterns spanning the entire seat areas on the reticle. In some embodiments, a traditional QTM seat design is further broken into cells that include an anchor feature (e.g., transition regions) for the optical tool to perform cell-to-cell comparisons rather than being limited to seat to seat, or even field to field, comparisons that can span vast distances.

For example, with cell level analysis, neighboring cel regions with separation distances around 4.5 microns may be compared with each other rather than neighboring seats or fields with distances on the order of mil-meters or centi-meters. This can substantially reduce noise. For example, with some exemplary C2C (cell-to-cell) implementations, the average noise was observed to be reduced by 24%, corresponding to the SNR being elevated by 31%.

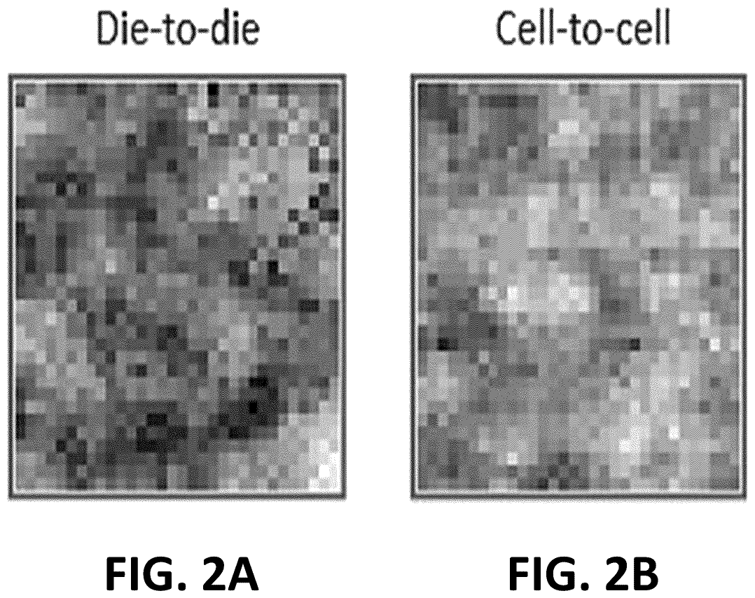

FIGS. 2A and 2B show exemplary defect reference images from die-to-die and cell-to-cell comparisons. For defect detection, reference images are used to identify defective regions compared to a background. If the reference image is noisy (as with the D2D case as compared with the C2C case), the comparison will yield more false positives, which hinders the identification (or detection) of true defects. It can be seen that the C2C case shows a more uniform reference image, resulting in less accurately interpreted anomalies by the optical defect analysis system.

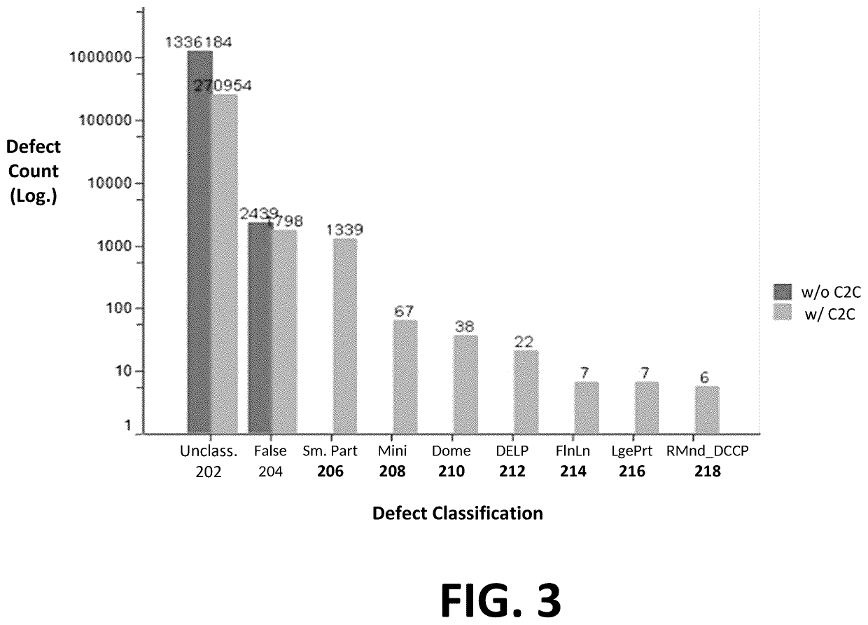

FIG. 3 is a graph showing defect pareto results for die-to-die and cell-to-cell optical defect detection cases. Improvement on the reference image yields higher SNR, which translates to more accurate defect identification. With this figure, side-by-side results demonstrate the benefit of adding design-based cell-to-cell defect inspection. For example, nuisance (e.g., false) defects (602, 604) are larger for the process without C2C comparison. In addition, the other optically identified categories, which correspond to actual defects, can be identified, in most cases with the C2C but not the other comparison process. This is because these harder to detect defects require higher SNR, which may be provided by C2C comparison techniques.

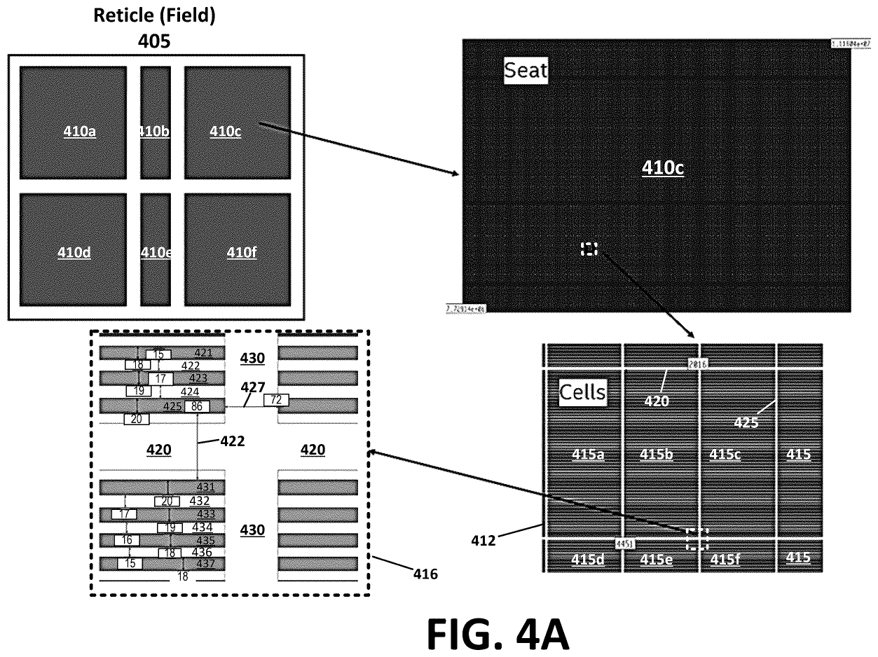

FIG. 4A is a diagram showing a defect test reticle layout using cells and cell transition regions between the cells in accordance with some embodiments. The figure shows a reticle field 405 that includes six seats (610a-610f) in this example. Note that four of the seats (610a, 610c, 610d, 610f) are larger than the other two seats (610b, 610e). Depending on design considerations, seats may or may not be used, and if used, they need not be the same, although more of the same seats/cells may lead to better optical image comparison analysis for some scenarios.

The figure shows an enlarged seat 410c taken from the field 405. The seat includes a large number of cells, e.g., around three or four thousand cells. A very small box-shaped section is shown with an enlarged view (412). This small portion of the seat includes cells 415 which are delineated with horizontal transition regions 420 and vertical transition regions 430. In some embodiments, these transition regions may be in the neighborhood of 60 to 90 nm in width. With the depicted example, the transition regions are implemented with photo-resist layer space that doesn't include a relevant feature (e.g., trench line) being analyzed. It should be appreciated, however, that transition regions may be implemented with any suitable structure, e.g., with an absence of something, e.g., resist without feature or etched away space, or with an added structure such as a material deposited into a trench, or a material remaining after etching or from a deposition process.

With particular relevance to this disclosure, a portion of the cell-level section 412 is shown within dashed box 416. This is an enlarged view featuring a region where transition regions intersect cells 415b, 415c, 415e, and 415f.

In this view, trench features (dark gray) are shown as they are disposed within a photo resist layer (white). These features (trenches and photo-resist lines) are aligned with each other, as well as with the horizontal transition regions 420.

The view also shows dimension values for the features. Here, the dimension values are shown for features on the left side of transition region 430. For example, the widths of trenches 431, 433, 435, 437 are 20, 19, 18, and 18 nanometers, respectively. Likewise, the widths of resist lines 432, 434, 436 are 17, 16, and 15 nano-meters, respectively. These features, which are below the aligned transition region (420) are mirrored to those that are above it. That is, trenches 421, 423, 425 are 18, 19, and 20 nano-meters, respectively. Similarly, resist lines 422, 424 are 15 and 17 nano-meters, respectively.

It can be seen that the feature widths, at least for features aligned with a transition region, start to become wider, at a certain point, as they become closer to the aligned transition region. For purposes of this disclosure, this is referred to as fanned out features. That is, when features are fa0nned out, as used herein, for at least some of the features that are aligned with a transition region, they become wider as they get closer to the transition region.

With this example, the fanning out applies to the three aligned trenches and two aligned resist lines that are closest to a corresponding transition region. The features are configured this way (wider as they become closer to an aligned transition region) to avoid predictable defects that will occur, e.g., for aligned features that are relatively small and close enough to a CDC transition region. That is, the fanned out features help the pattern to print correctly in the lithography tool. When they are not fanned out, as seen in FIG. 4B, there are missing lines, resulting from the lithographic process. Because these missing lines are caused by the lines'proximity to the transition region, they are called “systematic” defects.

In some embodiments for detecting process issues, rarer “stochastic” defects, which occur randomly and can form anywhere in the cell, are what is being sought for detection. So, the predictable systematic defects can get in the way of detecting the random, stochastic process defects, which are of interest. For example, the defect inspection tool can capture smaller blocked trench defects that are of interest, but the predictable, larger, transition-region causing defects can impair the inspection tool's ability to more clearly detect such defects.

In FIG. 4C it can be seen that the lithography tool can print the fanned out features correctly. Now the defect inspection tool will not flag systematic missing lines (as it would have for the FIG. 4B case), but instead would flag only stochastic blocked trench defects for this example.

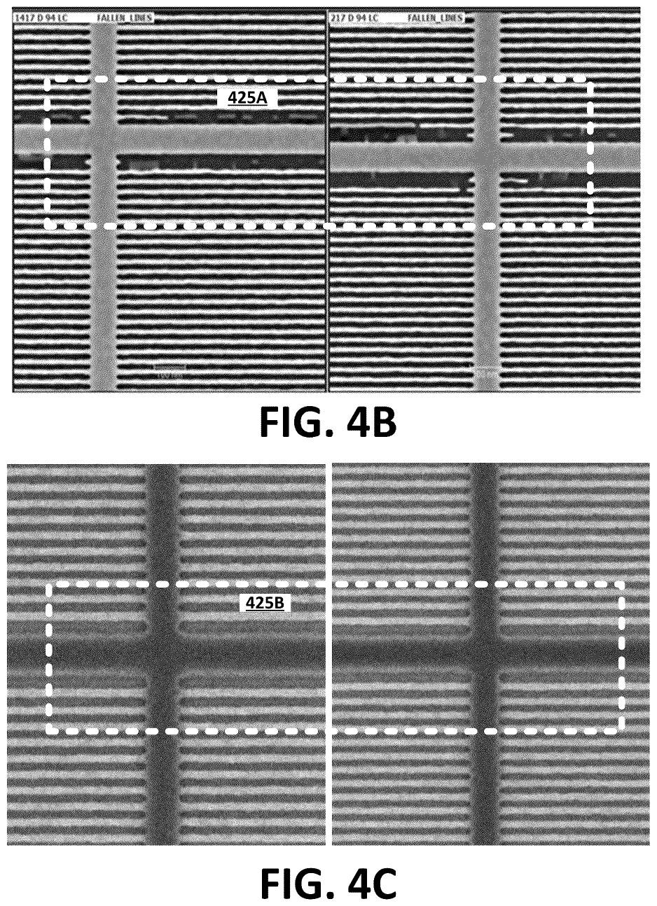

FIG. 5 is a block diagram showing an exemplary optical defect identification system 505 in accordance with some embodiments. For example, the depicted system may be part of a QTM system in a semiconductor fabrication foundry. The system 505 includes a controllably moveable pedestal 510 for supporting and adjusting the position of a semiconductor test wafer 502 in order to image it. It also has an optical imaging assembly 515 including processing system circuitry 520 with memory 525 for controlling the optical imaging assembly to perform QTM cell comparisons to identify feature defect candidates for further analysis. The optical imaging assembly 515 may be implemented with any suitable device for QTM wafer defect inspection and/or identification. For example, a 39xx Series Wafer Defect Inspection tool from KLA Corp™ may be used in some implementations.

The processing system circuit 520 may be implemented with one or more processors, controllers, finite state machine circuits and/or combinations of the same. It may correspond to dedicated processing system circuitry for a QTM optical imaging apparatus, itself, or it may be implemented with a combination of dedicated optical imaging assembly control/processing circuitry and/or with apps or other modules running, for example, on a semiconductor processing system server. In some embodiments, the processing system circuitry may also be coupled with control systems for controlling the X-Y position of pedestal 505 and/or the optical image assembly 515 itself to scan and image a test wafer 502.

Memory 525 may include instructions that when executed by processing system 520 control and/or implement operation of the optical image assembly 515, as well as image comparison analysis to identify defect candidates, for example, by generating defect reference images. In some embodiments, it includes optical defect analysis software 527 to perform some or all of these functions. In some embodiments, AI-driven systems may be employed to analyze inspection results within minutes rather than hours by: Automatically classifying defects using pattern recognition algorithms and filtering false positives through statistical validation across multiple cells. With such systems, focused investigations (e.g., using e-beam microscopy) can be used on high-risk test wafer areas, for example, locations indicated from defect reference images generated by the optical system.

With the use of an optical defect inspection/identification system including an optical imaging assembly 515, inline wafers can be monitored for small defects (~15 nm), with high throughput (e.g., >1000 square cm/hour) even though the optical imaging resolution may be limited to 100 nm or higher. With this disparity, it becomes important to be able to enhance the achievable signal-to-noise ratio using methods as discussed herein. In particular, employing C2C comparison techniques in an inspection process can enable advanced detection approaches that can drive down noise, discriminate against nuisance defects and increase the signal-to-noise ratio for valid defects being scanned.

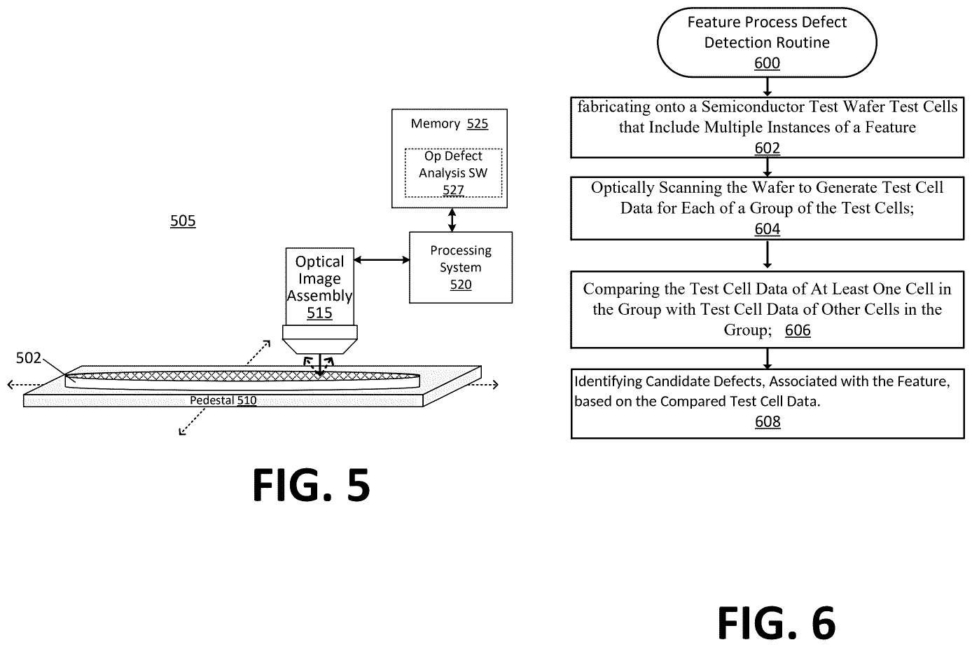

FIG. 6 is a flow diagram showing a routine for detecting defects in a semiconductor feature process in accordance with some embodiments. At 602, test cells that include multiple instances of a feature are fabricated onto a test wafer. The test cells are separated from one another with cell transition regions.

At 604, the wafer is optically scanned to generate test cell data for each of a group of the test cells. A group may be all of the cells on a wafer, like (comparable) cells, or a subset of like or unlike cells on a wafer, depending on specific design implementations. A group, however, will typically correspond to all or some of the cells on a wafer that are alike, e.g., are configured to be the same with equivalent feature types, layouts, sizes, etc.

At 606, the test cell data of at least one cell in the group is compared with test cell data of other cells in the group. At 608, candidate defects for the feature are identified. The identification is based on the compared test cell data.

Illustrative examples of the technologies disclosed herein are provided below. An embodiment of the technologies may include any one or more, and any compatible combination of, the examples described below.

Example 1 is a method that includes fabricating onto a semiconductor test wafer test cells that include multiple instances of a semiconductor feature, the test cells being separated from one another with cell transition regions. The method also includes optically scanning the wafer to generate test cell data for each of a group of the test cells, comparing the test cell data of at least one cell in the group with test cell data of other cells in the group, and identifying candidate defects, associated with the semiconductor feature, based on the compared test cell data.

Example 2 includes the subject matter of example 1, and wherein the semiconductor feature instances include parallel trenches in a material on the wafer.

Example 3 includes the subject matter of any of examples 1-2, and wherein the parallel trenches include first and second trenches that are aligned with a first one of the cell transition regions, wherein the first trench is closer than the second trench to the first cell transition region, and wherein the first trench is wider than the second trench.

Example 4 includes the subject matter of any of examples 1-3, and wherein the first trench is next to the first transition region, and the second trench is next to the first trench.

Example 5 includes the subject matter of any of examples 1-4, and wherein a first distance between the first transition region and the first trench is greater than a second distance between the first trench and the second trench.

Example 6 includes the subject matter of any of examples 1-5, and wherein the test cells each occupy an area less than 20 square microns.

Example 7 includes the subject matter of any of examples 1-6, and wherein the cell transition regions have widths of between 40 and 100 nano-meters.

Example 8 includes the subject matter of any of examples 1-7, and wherein fabricating includes step scanning multiple reticle fields onto the wafer, wherein each field includes a different group of the test cells.

Example 9 includes the subject matter of any of examples 1-8, and wherein the test cell groups include commonly configured test cells.

Example 10 includes the subject matter of any of examples 1-9, and wherein identifying candidate defects based on the compared test cell data. includes generating reference defect images based on the compared test cell data.

Example 11 is a process of making a test wafer. The process includes scanning onto the test wafer a frame pattern, the frame pattern including separate cells that include repeated first feature instances. The separate cells are delineated with transition regions, and for each cell, at least one of the first feature instances that is closer to an aligned transition region than another first feature instance is larger than the another first feature instance. The process also includes scanning onto the wafer in different locations additional instances of the frame pattern.

Example 12 includes the subject matter of example 11, and wherein the separate cells include second feature instances.

Example 13 includes the subject matter of any of examples 11-12, and wherein at least some of the separate cells are differently configured.

Example 14 includes the subject matter of any of examples 11-13, and wherein the first feature instances are parallel aligned trenches.

Example 15 includes the subject matter of any of examples 11-14, and wherein the parallel aligned trenches are parallel with the aligned transition region.

Example 16 includes the subject matter of any of examples 11-15, and wherein the separate cells each occupy less than 20 square microns.

Example 17 is a test wafer apparatus that includes a wafer substrate and a photo-resist layer disposed onto the wafer substrate. The photo-resist layer includes a plurality of test cell regions defined by transition regions, the test cell regions including parallel-aligned trenches that are aligned with at least one of the transition regions, wherein at least some of the parallel-aligned trenches that are closer to the at least one transition region than others of the parallel-aligned trenches are wider than the others of the parallel-aligned trenches.

Example 18 includes the subject matter of example 17, and wherein at least some of the parallel-aligned trenches include fanned-out trenches.

Example 19 includes the subject matter of any of examples 17-18, and wherein the transition regions are defined by photo-resist regions that do not contain feature trenches.

Example 20 includes the subject matter of any of examples 17-19, and wherein the transition regions are defined by regions in the photo-resist layer where photo-resist has been removed.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. A method, comprising:
fabricating onto a semiconductor test wafer test cells that include multiple instances of a semiconductor feature, the test cells being separated from one another with cell transition regions;
optically scanning the wafer to generate test cell data for each of a group of the test cells;
comparing the test cell data of at least one cell in the group with test cell data of other cells in the group; and
identifying candidate defects, associated with the semiconductor feature, based on the compared test cell data.

2. The method of claim 1, wherein the semiconductor feature instances include parallel trenches in a material on the wafer.

3. The method of claim 2, wherein the parallel trenches include first and second trenches that are aligned with a first one of the cell transition regions, wherein the first trench is closer than the second trench to the first cell transition region, and wherein the first trench is wider than the second trench.

4. The method of claim 3, wherein the first trench is next to the first transition region, and the second trench is next to the first trench.

5. The method of claim 4, wherein a first distance between the first transition region and the first trench is greater than a second distance between the first trench and the second trench.

6. The method of claim 1, wherein the test cells each occupy an area less than 20 square microns.

7. The method of claim 1, wherein the cell transition regions have widths of between 40 and 100 nano-meters.

8. The method of claim 1, wherein fabricating includes step scanning multiple reticle fields onto the wafer, wherein each field includes a different group of the test cells.

9. The method of claim 8, wherein the test cell groups include commonly configured test cells.

10. The method of claim 1, wherein identifying candidate defects based on the compared test cell data. includes generating reference defect images based on the compared test cell data.

11. A process of making a test wafer, comprising:
scanning onto the test wafer a frame pattern, the frame pattern including separate cells that include repeated first feature instances, the separate cells delineated with transition regions, wherein for each cell, at least one of the first feature instances that is closer to an aligned transition region than another first feature instance is larger than the another first feature instance; and
scanning onto the wafer in different locations additional instances of the frame pattern.

12. The process of claim 11, wherein the separate cells include second feature instances.

13. The process of claim 11, wherein at least some of the separate cells are differently configured.

14. The process of claim 11, wherein the first feature instances are parallel aligned trenches.

15. The process of claim 14, wherein the parallel aligned trenches are parallel with the aligned transition region.

16. The process of claim 11, wherein the separate cells each occupy less than 20 square microns.

17. A test wafer apparatus, comprising:
a wafer substrate; and
a photo-resist layer disposed onto the wafer substrate, the photo-resist layer including a plurality of test cell regions defined by transition regions, the test cell regions including parallel-aligned trenches that are aligned with at least one of the transition regions, wherein at least some of the parallel-aligned trenches that are closer to the at least one transition region than others of the parallel-aligned trenches are wider than the others of the parallel-aligned trenches.

18. The apparatus of claim 17, wherein at least some of the parallel-aligned trenches include fanned-out trenches.

19. The apparatus of claim 17, wherein the transition regions are defined by photo-resist regions that do not contain feature trenches.

20. The apparatus of claim 17, wherein the transition regions are defined by regions in the photo-resist layer where photo-resist has been removed.
